(19) United States
(12) Patent Application Publication
(10) Pub. No.: US 2005/0247960 A1
(43) Pub. Date: Nov. 10, 2005

(54) Method for fabricating multi-layer film for vacuum packaging and multi-layer film fabricated by the method

(75) Inventors: Yong Soo Rim, Daejeon (KR); Yong Ho Kwon, Daejeon (KR); Won Jung Choi, Daejeon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Barflex Corporation, Daejeon (KR)

(21) Appl. No.: 11/060,830

(22) Filed: Feb. 18, 2005

Related U.S. Application Data
(63) Continuation of application No. 10/903,378, filed on Jul. 30, 2004, now abandoned.

(30) Foreign Application Priority Data
May 4, 2004 (KR) 10-2004-0031302

(51) Int. Cl. H01L 29/74

(52) U.S. Cl. 257/211

(57) ABSTRACT

A method for fabricating a multi-layer film for vacuum packaging, comprises the steps of: supplying a gas-impermeable film to a cooling roll; supplying a sealing film to a nip roll having an embossed pattern; extruding a molten polymer material toward a gap between the gas-impermeable film and the sealing film, thereby forming a multi-layer preform having a structure of gas-impermeable film-polymer layer-sealing film; and squeezing the multi-layer preform by passing the multi-layer preform through a nip between the nip roll and the cooling roll, so that the gas-impermeable film, the sealing film, and the polymer material of the multi-layer preform are laminated on each other simultaneously while the sealing film and the polymer material are embossed by the nip roll and the cooling roll.

### BACKGROUND OF THE INVENTION

1. Field of the Invention

The present invention relates to a method for fabricating a multi-layer film for vacuum packaging, and more particularly to a method for fabricating a multi-layer film for vacuum packaging and a multi-layer film manufactured by the method, in which the multi-layer film has air channels formed on a lower surface thereof, so as to prevent local entrapment of air between an object and the multi-layer film when the object is packaged by the multi-layer film.

2. Description of the Related Art

As generally known in the art, vacuum packaging is one of the methods for storing contents such as food for long time. When contents are packed by the vacuum packaging, air is removed from an inside of a package, thereby efficiently preventing the contents contained in the package from becoming rotten or spoiled.

In typical vacuum packaging, contents to be packaged is placed in a packaging bag made of a predetermined film, and an opening of the packaging bag is then heated and sealed while air is vacuum-sucked from the inside of the packaging bag.

However, during the vacuum packaging, the contents and the packaging bag may locally come into contact with each other at several portions, which may prevent air from going out of the packaging bag and may capture air in gaps between the portions and the packaging bag, thereby greatly deteriorating the utility of the vacuum packaging.

In order to solve the above problems, various constructions or methods for forming air discharge channels in a packaging bag made of a film or wrap have been proposed.

For example, U.S. Pat. No. 2,778,173 discloses a method for removing air from an inside of a package by forming air channels on a film of the package. However, U.S. Pat. No. 2,778,173 discloses only a forming roll having a serration for forming air channels on the package film but does not disclose a specific way how the forming roll forms the air channels.

Further, U.S. Pat. No. 4,756,422 discloses a method for fabricating a plastic bag for vacuum sealing, in which air channels connected with each other are formed in a package film. In U.S. Pat. No. 4,756,422, the film is heated up to its plasticity temperature and is then made to pass through a gap between rolls having embossed patterns while being compressed, so that a film having an embossed pattern is formed. However, during the thermal rolling, portions of the film compressed by the embossed pattern may become thinner, so that the film may be broken or pinholes may formed in the film, which increases the probability of defective goods.

Further, U.S. Pat. No. 5,554,423 discloses a method for fabricating a vacuum packing bag having air channels formed therein. In U.S. Pat. No. 5,554,423, the air channels are formed by longitudinally attaching polyolefin-based polymer materials to a film without using the embossing, so as to eliminate the possibility of breakage of the film or generation of pinholes in the film. However, U.S. Pat. No. 5,554,423 requires a separate step for longitudinally attaching the polymer materials to the film, which makes the entire process complicated. Further, high temperature and high pressure required for the attachment of the polymer material cause another problem, difficulty in controlling the high temperature and high pressure.

Further, the prior arts include another method for fabricating a multi-layer package film for vacuum packing, in which a sealing polymer material is extrusion-coated on a single layer film, and the extrusion-coated film is then made to pass through a gap between a forming roll having an embossed pattern formed thereon and a nip roll, so that a sealing polymer layer is laminated on the single layer film. However, in this method, the hot molten sealing polymer material comes into direct contact with the embossed pattern of the forming roll having a non-uniform outer surface, which causes a difference in cooling speed between local areas of the sealing polymer material. As a result, air may be introduced into the polymer layer during the cooling, so that the polymer-laminated multi-layer package film may have either pinholes generated in the polymer layer or deteriorated transparency.

### SUMMARY OF THE INVENTION

Accordingly, the present invention has been made to solve the above-mentioned problems occurring in the prior art, and an object of the present invention is to provide a method for fabricating a multi-layer film for vacuum packaging, which can form air channels on a lower surface of the multi-layer film, while enabling the multi-layer film to have a good transparency and preventing the multi-layer film from being broken or damaged.

It is another object of the present invention to provide a multi-layer film for vacuum packaging, which can form air channels on a lower surface of the multi-layer film, while enabling the multi-layer film to have transparency and preventing the multi-layer film from being broken or damaged.

In order to accomplish this object, there is provided a method for fabricating a multi-layer film for vacuum packaging, the method comprising the steps of: supplying a gas-impermeable film to a cooling roll; supplying a sealing film to a nip roll having an embossed pattern; extruding a molten polymer material toward a gap between the gas-impermeable film and the sealing film, thereby forming a multi-layer preform having a structure of gas-impermeable film-polymer layer-sealing film; and squeezing the multi-layer preform by passing the multi-layer preform through a nip between the nip roll and the cooling roll, so that the gas-impermeable film, the sealing film, and the polymer material of the multi-layer preform are laminated on each other simultaneously while the sealing film and the polymer material are embossed by the nip roll and the cooling roll.

In accordance with another aspect of the present invention, there is provided a multi-layer film for vacuum packaging, comprising: a gas-impermeable film; a sealing film having an embossed pattern formed thereon; and a polymer layer formed between the gas-impermeable film and the sealing film and having the embossed pattern formed thereon, wherein the gas-impermeable film, the sealing film, and the polymer layer are laminated on each other simultaneously while the embossed pattern is formed on the sealing film and the polymer layer by extrusion-coating a molten polymer material into a gap between the gas-impermeable film passing via a cooling roll and the sealing film passing via a nip roll adjacent to the cooling roll and then passing a multi-layer perform consisting of the gas-impermeable film-polymer layer-sealing film through a nip between the nip roll and the cooling roll in a squeezed state, the nip roll having an embossing pattern.

In accordance with still another aspect of the present invention, there is provided a vacuum packaging bag comprising a multi-layer film for vacuum packaging as described above.

Preferably, the sealing film is a polyolefin-based film containing one selected from the group consisting of low density polyethylene (LDPE), linear low density polyethylene (LLDPE), high density polyethylene (HDPE), polypropylene (PP), ethylene-vinylacetate copolymer (EVA), ethylene-acryl acid copolymer (EAA), and ethylene-methylacrylate copolymer (EMA).

Preferably, the gas-impermeable film includes at least one layer made from a polyolefin-based material, and each of the sealing film and the polymer layer is a polyolefin-based film.

The gas-impermeable film may be a complex film fabricated by laminating or co-extruding a nylon film, a polyester film, and an ethylene-vinyl alcohol copolymer (EVOH) film, or a complex film fabricated by laminating or co-extruding polyolefin with at least one of a nylon film, a polyester film, and an ethylene-vinyl alcohol copolymer film.

Preferably, the sealing film may contain, as additives, at least one of an antibiotic material, an anti-fog material for preventing formation of droplets, and an aromatic material for providing fragrance to the sealing film.

More preferably, the sealing film is an air-cooled film fabricated through an extrusion according to a blown method.

The method for fabricating a multi-layer film for vacuum packaging as described above may further comprise a step of preheating the gas-impermeable film and the sealing film before the polymer material is extruded.

It is preferred that the gas-impermeable film has an oxygen permeability smaller than or equal to 200 cc/m²·24 hrs·atm.

Preferably, the polymer material is a polyolefin-based material equal to that from which the sealing film is made.

The embossed pattern may have a shape selected from the group consisting of shapes of parallel lines, slant lines, wave lines, spiral lines, and crossing lines thereof. Preferably, the embossed pattern may include at least one of a letter and a character in addition to the selected shape.

### BRIEF DESCRIPTION OF THE DRAWINGS

The above and other objects, features and advantages of the present invention will be more apparent from the following detailed description taken in conjunction with the accompanying drawings, in which:

FIG. 1 is a schematic diagram illustrating a process for fabricating a multi-layer film for vacuum packaging, including a laminating step, an extrusion-coating step, and an embossing step;

FIG. 2 is a cross-sectional view of a multi-layer film for vacuum packaging fabricated according to the process shown in FIG. 1;

FIG. 3 illustrates embossing patterns having various shapes, which may be formed on an outer surface of a nip roll for the embossing step; and

FIG. 4 is a schematic perspective view of a vacuum packaging bag fabricated using the multi-layer film shown in FIG. 2.

### DETAILED DESCRIPTION OF THE PREFERRED EMBODIMENT

Hereinafter, a preferred embodiment of the present invention will be described with reference to the accompanying drawings.

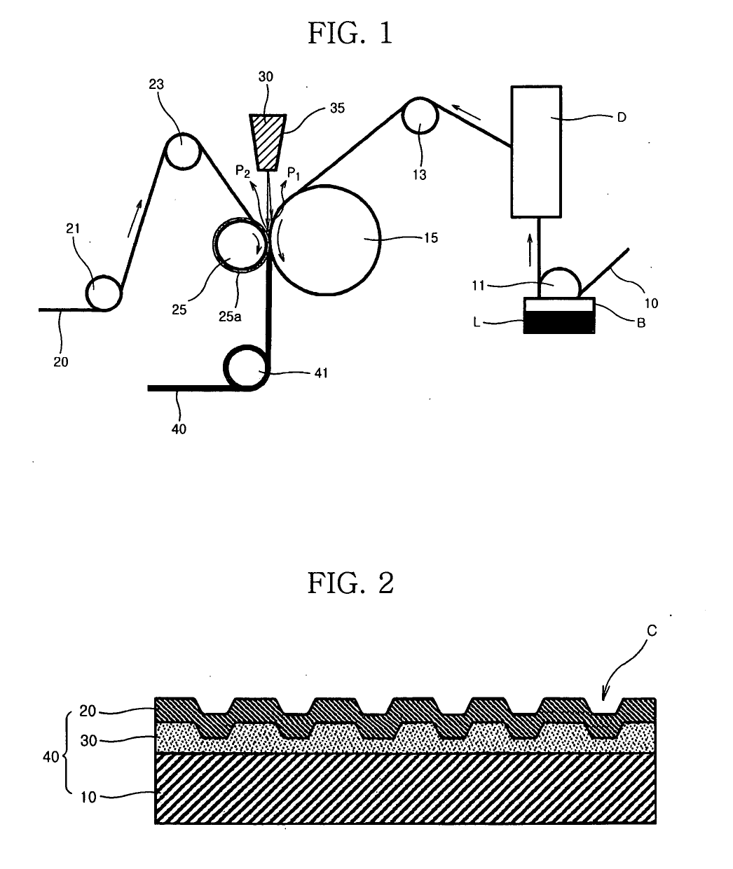

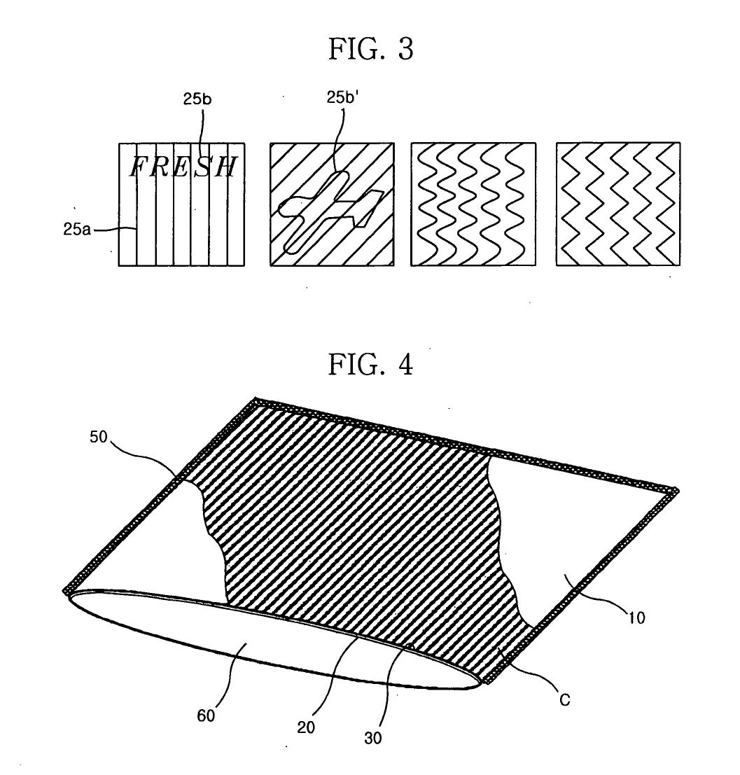

FIG. 1 is a schematic diagram illustrating a system and a process for fabricating a multi-layer film for vacuum packaging, including a laminating step, an extrusion-coating step, and an embossing step.

As shown, a system for fabricating a multi-layer film for vacuum packaging according to the present invention includes guide rolls 11 and 13 for guiding a gas-impermeable film 10, guide rolls 21 and 23 for guiding a sealing film 20, a T-die 35 of an extruding machine for extruding a molten polymer material in a shape of a sheet, and a cooling roll 15 and a nip roll 25 disposed adjacently to each other under the T-die 35, so as to draw the gas-impermeable film 10 and the sealing film 20 and perform laminating and embossing for the gas-impermeable film 10 and the sealing film 20. Here, the nip roll 25 has an embossed pattern formed on an outer surface of the nip roll 25, for the performance of the embossing.

Hereinafter, a process for fabricating a multi-layer film for vacuum packaging according to the present invention, utilizing the system as described above, will be described.

The gas-impermeable film 10 is supplied from a supply roll (not shown) through the guide rolls 11 and 13 to the cooling roll 15.

At the same time, the sealing film 20 is supplied from another supply roll (not shown) through the guide rolls 21 and 23 to the nip roll 25.

A molten polymer material 30 extruded through the T-die 35 of the extruding machine is supplied into the gap between the gas-impermeable film 10 and the sealing film 20 wound on and carried by the cooling roll 15 and the nip roll 25 in a shape of a sheet, thereby extrusion-coating the gas-impermeable film 10 and the sealing film 20 with the polymer material 30.

Here, while the gas-impermeable film 10 and the sealing film 20 are extrusion-coated in the way described above, they are also squeezed and carried between the cooling roll 15 and the nip roll 25. As a result, a multi-layer film or lamination of gas-impermeable film-polymer layer-sealing film is obtained.

Here, an embossed pattern 25a having various shapes is formed on an outer surface of the nip roll 25, so that the sealing film 20 and the polymer material 30 are embossed during the lamination, thereby forming air channels c as shown in FIG. 2.

Through the above-mentioned process, a multi-layer film 40 for vacuum packaging as shown in FIG. 2 is finally produced. Then, the multi-layer film 40 is moved through a guide roll 41 to a storage roll (not shown).

The finally-produced multi-layer film 40 for vacuum packaging has a multi-layer structure including a flat gas-impermeable film 10, an embossed polymer layer 30, and an embossed sealing film 20, which are sequentially laminated on each other.

Hereinafter, a mechanism of such lamination and embossing for the multi-layer film as described above, performed while the films pass through the nip between the cooling roll 15 and the nip roll 25, will be described.

Since the molten polymer material 30 is extrusion-coated between the gas-impermeable film 10 and the sealing film 20 passing through the cooling roll 15 and the nip roll 25 has a thermal energy of a high temperature, surfaces of the gas-impermeable film 10 and the sealing film 20 in contact with the polymer material 30 absorb the thermal energy of the polymer material 30, so that a temperature of the surfaces increase up to a level which enables a thermal forming of the surfaces.

In this state, when the gas-impermeable film 10 and the sealing film 20 pass through the nip between the cooling roll 15 and the nip roll 25, the pressing of the gas-impermeable film 10 and the sealing film 20 onto each other by the cooling roll 15 and the nip roll 25 further promotes the heat transfer from the polymer material 30 between the gas-impermeable film 10 and the sealing film 20 to the contact surfaces of the gas-impermeable film 10 and the sealing film 20, thereby facilitating satisfaction of conditions for enabling the lamination of the polymer material 30 on the contact surfaces.

In other words, at an initial stage of the extrusion coating, the hot polymer material 30 preheats the contact surfaces of the gas-impermeable film 10 and the sealing film 20 in contact with the hot polymer material 30. Then, while the gas-impermeable film 10 and the sealing film 20 extrusion-coated with the polymer material 30 pass through the nip between the cooling roll 15 and the nip roll 25, the pressing of the gas-impermeable film 10 and the sealing film 20 onto each other by the cooling roll 15 and the nip roll 25 promotes the heat transfer, thereby enabling the contact surfaces of the gas-impermeable film 10 and the sealing film 20 to enter a state sufficiently proper for the lamination of the polymer material thereon. Finally, the lamination structure described above is achieved.

Here, since the state proper for the lamination enables the sealing film 20 and the polymer material 30 to be embossed by the embossed pattern 25a of the nip roll 25, the laminating and the embossing are simultaneously carried out. The embossed pattern formed through the embossing forms air channels for a vacuum package, through which air can be discharged out of the vacuum package, when a predetermined object is packed in the vacuum package using the multi-layer film.

The embossed pattern 25a may be formed in various shapes. For example, the embossed pattern 25a may have a shape selected from the group consisting of shapes of parallel lines, slant lines, wave lines, spiral lines, and crossing lines thereof. Preferably, the embossed pattern 25a may includes at least one of a letter 25b and a character 25b′.

In fabricating the multi-layer film for vacuum packaging, only the gas-impermeable film 10 is not embossed, since the gas-impermeable film 10 is wound on and carried by the cooling roll 15 and is thus cooled to be in an insufficient preheated state.

The gas-impermeable film 10 forms an outermost layer of the multi-layer film 40 for vacuum packaging and must have properties suitable for vacuum packaging. Therefore, the gas-impermeable film 10 must have a low gas permeability. Preferably, the gas-impermeable film 10 has an oxygen permeability not larger than 200 cc/m²·24 hrs·atm. When the gas-impermeable film 10 has an oxygen permeability exceeding this limit, air or oxygen may enter a vacuum package through the gas-impermeable film 10, deteriorating a stored state of an object in the vacuum package even after the object is packed in the vacuum package.

The gas-impermeable film 10 is a complex film made by laminating or co-extruding a nylon film, a polyester film, and an ethylene-vinyl alcohol copolymer (EVOH) film or a complex film made by laminating or co-extruding polyolefin with at least one of a nylon film, a polyester film, and an ethylene-vinyl alcohol copolymer film.

The sealing film 20 forms an innermost layer of the multi-layer film 40 for vacuum packaging and is embossed simultaneously with the lamination. The embossed pattern of the sealing film 20 serving as air channels for air discharge enables the sealing film 20 to be in close contact with an object, thereby enabling the sealing film 20 to vacuum-package the object.

The sealing film 20 may be formed to have various functions, for example, the sealing film 20 may be made from a material containing an antibiotic material as an additive in order to improve the quality of preservation for the object, a material containing a low molecular anti-fog material as an additive in order to prevent formation of droplets on a surface of the sealing film 20 by reducing the surface tension of the droplets, or a material containing an aromatic material as an additive in order to enable the sealing film 20 to generate fragrance according to necessities.

Herein, the additive, such as an antibiotic material, anti-fog material, or an aromatic material, is added to the sealing film 20 when the sealing film 20 is fabricated, so that the completed sealing film 20 contains the additive. Further, in order to prevent the additive from being lost due to heat while the multi-layer film is fabricated, it is preferred that the sealing film is fabricated in a form of an air-cooled film through an extrusion according to a “blown method”.

In the above-mentioned “blown extrusion”, the temperature during the process reaches no more than a scale between 170° C. and 230° C. Therefore, there is no danger to lose such an additive as described above due to high-temperature heat.

If the sealing film is fabricated in the direct extrusion by a T-die as in the conventional way, the temperature reaches a scale between 230° C. and 330° C. while the sealing film is extruded and laminated on a predetermined base film for vacuum packaging. Therefore, it is difficult for a sealing film fabricated according to the conventional method to have a desired function, since a predetermined additive for providing the desired function may be lost due to the high-temperature heat.

Preferably, the sealing film 20 is a polyolefin-based film containing one selected from the group consisting of low density polyethylene (LDPE), linear low density polyethylene (LLDPE), high density polyethylene (HDPE), polypropylene (PP), ethylene-vinylacetate copolymer (EVA), ethylene-acryl acid copolymer (EAA), and ethylene-methylacrylate copolymer (EMA).

It is preferred that the polymer material 30 is the same polyolefin-based film as the sealing film 20, so as to facilitate lamination of them to each other.

Hereinafter, the present invention will be described in more detail through an example and a comparative example of the multi-layer film for vacuum packaging fabricated through the above-mentioned process, which are taken only exemplarily and do not limit the scope of the present invention.

### EXAMPLE 1

A multi-layer film for vacuum packaging was fabricated by the system as shown in FIG. 1, using a five-layered film of nylon/EVOH/adhesive resin/polyethylene/polyethylene having a thickness 60 μm as the gas-impermeable film, a single-layered linear low density polyethylene film having a thickness the polymer material 30 μm as the sealing film, and low density polyethylene as the polymer.

The extrusion coating was performed by extruding polymer having a melt index of the gas-impermeable film 10 at a speed of 50 kg/hr under a temperature of 300° C., and the extrusion-coated gas-impermeable film and sealing film were laminated and embossed by means of the cooling roll and the nip roll, so that the multi-layer for vacuum packaging was completely fabricated.

The embossed multi-layer film for vacuum packaging finally produced was observed by naked eyes to have a good transparency and confirmed to have good embossed portions and uniformly distributed air channels.

### COMPARATIVE EXAMPLE 1

A multi-layer film for vacuum packaging was fabricated under the same conditions as those in example 1, except for absence of the step of supplying the sealing film.

The multi-layer film for vacuum packaging produced through comparative example 1 was observed by naked eyes to have larger cloudiness and a lower transparency than the multi-layer film fabricated through example 1.

In comparative example 1, a molten polymer is in direct contact with the nip roll, so that the embossed pattern of the nip roll causes the cooling speed to be non-uniform and allows formation of pinholes in the surface polymer layer through air introduction into the surface polymer layer, thereby having bad influence on the transparency of the polymer layer.

Meanwhile, the present invention provides not only the method of fabricating a multi-layer film for vacuum packaging as described above but also a multi-layer film fabricated through the method and a vacuum-packaging bag using the multi-layer film.

The multi-layer film 40 for vacuum packaging according to the present invention includes: a gas-impermeable film 10 supplied to a cooling roll 15; a sealing film 20 supplied to a nip roll 25 having an embossed pattern 25a formed thereon; and a molten polymer material 30 supplied through extrusion to a gap between the gas-impermeable film 10 and the sealing film 20 to be attached to the gas-impermeable film 10 and the sealing film 20, thereby forming a multi-layer preform, wherein the multi-layer preform is made to pass through the nip between the nip roll and the cooling roll so that the gas-impermeable film 10, the sealing film 20, and the polymer material 30 of the multi-layer preform are laminated on each other simultaneously while the sealing film 20 and the polymer material 30 are embossed by the nip roll and the cooling roll.

The multi-layer film 40 for vacuum packaging fabricated through the above-mentioned process may be used to form a bag for vacuum packaging.

In fabricating the bag for vacuum packaging, two sheets of the above-described multi-layer film 40, each including the gas-impermeable film 10, the sealing film 20, and the polymer layer 30, are stacked on each other, and three sides thereof, thus excepting for only one side thereof, are sealed by heating said three sides. Therefore, a vacuum packaging bag having a heat-sealed rim 50 formed along three sides thereof and a bag mouth formed at one side thereof is produced.

FIG. 4 shows a vacuum packaging bag including a vacuum packaging film sheet having air channels c formed therein formed through the above-mentioned fabricating method and another vacuum packaging film sheet 60 having no air channel. It is possible for a vacuum packaging bag according to the present invention to have such a structure as shown in FIG. 4, since the air channels formed at only one sheet are enough for meeting the object of discharging air out of the bag.

The present invention provides a method of fabricating a multi-layer film for vacuum packaging, a multi-layer film fabricated by the method, and a vacuum packaging bag fabricated by the multi-layer film, in which the multi-layer film has air channels without breakage or damage of the film.

Although a method of fabricating a multi-layer film for vacuum packaging, a multi-layer film fabricated by the method, and a vacuum packaging bag fabricated by the multi-layer film, according to preferred embodiments of the present invention, have been described for illustrative purposes, those skilled in the art will appreciate that various modifications, additions and substitutions are possible, without departing from the scope and spirit of the invention as disclosed in the accompanying claims.

For example, in relation to the construction shown in FIG. 1, the gas-impermeable film 10 may be supplied through an adhesive reservoir B for applying adhesive on the gas-impermeable film 10 and through a drying unit D for drying the applied adhesive, in preparation for the case in which the polymer material 30 is not coated with a sufficient adhesive force on the gas-impermeable film 10 due to the cooling effect by the cooling roll 15.

Further, in order to enhance the adhesiveness of the polymer material 30 to the gas-impermeable film 10 wound and carried by the cooling roll 15, the extrusion of the polymer material 30 through the T-die 35 of the extruding machine may be carried out at a position P1 nearer to the gas-impermeable film instead of the exactly middle position between the gas-impermeable film and the sealing film. This biased position of the extrusion provides a sufficient preheating time for the gas-impermeable film 10 and enables the gas-impermeable film 10 to have a longer preheating time than the sealing film 20, thereby compensating for the cooling of the gas-impermeable film 10 by the cooling roll and preventing a possibility of deterioration in the adhesiveness.

Further, in order to enable the polymer material to be easily stuck to the sealing film and the gas-impermeable film, the guide rolls 13 and 23 may preferably have a preheating function so that the sealing film and the gas-impermeable film can be preheated after the extrusion-coating and before the laminating and embossing.

As described above, those skilled in the art will appreciate that various modifications, additions and substitutions are possible, without departing from the scope and spirit of the invention as disclosed in the accompanying claims.

1. A method for fabricating a multi-layer film for vacuum packaging, the method comprising the steps of:
supplying a gas-impermeable film to a cooling roll;
supplying a sealing film to a nip roll having an embossed pattern;
extruding a molten polymer material toward a gap between the gas-impermeable film and the sealing film, thereby forming a multi-layer preform having a structure of gas-impermeable film-polymer layer-sealing film; and
squeezing the multi-layer preform by passing the multi-layer preform through a nip between the nip roll and the cooling roll, so that the gas-impermeable film, the sealing film, and the polymer material of the multi-layer preform are laminated on each other simultaneously while the sealing film and the polymer material are embossed by the nip roll and the cooling roll.

2. A method for fabricating a multi-layer film for vacuum packaging as claimed in claim 1, wherein the sealing film is a polyolefin-based film containing one selected from the group consisting of low density polyethylene (LDPE), linear low density polyethylene (LLDPE), high density polyethylene (HDPE), polypropylene (PP), ethylene-vinylacetate copolymer (EVA), ethylene-acryl acid copolymer (EAA), and ethylene-methylacrylate copolymer (EMA).

3. A method for fabricating a multi-layer film for vacuum packaging as claimed in claim 1, wherein the gas-impermeable film includes at least one layer made from a polyolefin-based material, and each of the sealing film and the polymer layer is a polyolefin-based film.

4. A method for fabricating a multi-layer film for vacuum packaging as claimed in claim 1, wherein the gas-impermeable film is a complex film fabricated by laminating or co-extruding a nylon film, a polyester film, and an ethylene-vinyl alcohol copolymer (EVOH) film.

5. A method for fabricating a multi-layer film for vacuum packaging as claimed in claim 1, wherein the gas-impermeable film is a complex film fabricated by laminating or co-extruding polyolefin with at least one of a nylon film, a polyester film, and an ethylene-vinyl alcohol copolymer film.

6. A method for fabricating a multi-layer film for vacuum packaging as claimed in claim 2, wherein the polymer material is a polyolefin-based material equal to that from which the sealing film is made.

7. A method for fabricating a multi-layer film for vacuum packaging as claimed in claim 2, wherein the sealing film contains, as additives, at least one of an antibiotic material, an anti-fog material for preventing formation of droplets, and an aromatic material for providing fragrance to the sealing film.

8. A method for fabricating a multi-layer film for vacuum packaging as claimed in claim 2, wherein the sealing film is an air-cooled film fabricated through an extrusion according to a blown method.

9. A method for fabricating a multi-layer film for vacuum packaging as claimed in claim 1, further comprising a step of preheating the gas-impermeable film and the sealing film before the polymer material is extruded.

10. A method for fabricating a multi-layer film for vacuum packaging as claimed in claim 1, wherein the gas-impermeable film has an oxygen permeability smaller than or equal to 200 cc/m²·24 hrs·atm.

11. A method for fabricating a multi-layer film for vacuum packaging as claimed in claim 1, wherein the embossed pattern has a shape selected from the group consisting of shapes of parallel lines, slant lines, wave lines, spiral lines, and crossing lines thereof.

12. A method for fabricating a multi-layer film for vacuum packaging as claimed in claim 11, wherein the embossed pattern includes at least one of a letter and a character in addition to the selected shape.

13. A multi-layer film for vacuum packaging, comprising:
a gas-impermeable film;
a sealing film having an embossed pattern formed thereon; and
a polymer layer formed between the gas-impermeable film and the sealing film and having the embossed pattern formed thereon, wherein
the gas-impermeable film, the sealing film, and the polymer layer are laminated on each other simultaneously while the embossed pattern is formed on the sealing film and the polymer layer by extrusion-coating a molten polymer material into a gap between the gas-impermeable film passing via a cooling roll and the sealing film passing via a nip roll adjacent to the cooling roll and then passing a multi-layer perform consisting of the gas-impermeable film-polymer layer-sealing film through a nip between the nip roll and the cooling roll in a squeezed state, the nip roll having an embossing pattern.

14. A multi-layer film for vacuum packaging as claimed in claim 13, wherein the sealing film is a polyolefin-based film containing one selected from the group consisting of low density polyethylene (LDPE), linear low density polyethylene (LLDPE), high density polyethylene (HDPE), polypropylene (PP), ethylene-vinylacetate copolymer (EVA), ethylene-acryl acid copolymer (EAA), and ethylene-methylacrylate copolymer (EMA).

15. A multi-layer film for vacuum packaging as claimed in claim 13, wherein the gas-impermeable film includes at least one layer made from a polyolefin-based material, and each of the sealing film and the polymer layer is a polyolefin-based film.

16. A multi-layer film for vacuum packaging as claimed in claim 13, wherein the gas-impermeable film is a complex film fabricated by laminating or co-extruding a nylon film, a polyester film, and an ethylene-vinyl alcohol copolymer (EVOH) film.

17. A multi-layer film for vacuum packaging as claimed in claims 13, wherein the gas-impermeable film is a complex film fabricated by laminating or co-extruding polyolefin with at least one of a nylon film, a polyester film, and an ethylene-vinyl alcohol copolymer film.

18. A multi-layer film for vacuum packaging as claimed in claim 14, wherein the polymer material is a polyolefin-based material equal to that from which the sealing film is made.

19. A multi-layer film for vacuum packaging as claimed in claim 14, wherein the sealing film contains, as additives, at least one of an antibiotic material, an anti-fog material for preventing formation of droplets, and an aromatic material for providing fragrance to the sealing film.

20. A multi-layer film for vacuum packaging as claimed in claim 14, wherein the sealing film is an air-cooled film fabricated through an extrusion according to a blown method.

21. A multi-layer film for vacuum packaging as claimed in claim 13, wherein the gas-impermeable film has an oxygen permeability smaller than or equal to 200 cc/m²·24 hrs·atm.

22. A multi-layer film for vacuum packaging as claimed in claim 13, wherein the embossed pattern has a shape selected from the group consisting of shapes of parallel lines, slant lines, wave lines, spiral lines, and crossing lines thereof.

23. A multi-layer film for vacuum packaging as claimed in claim 22, wherein the embossed pattern includes at least one of a letter and a character in addition to the selected shape.

24. A vacuum packaging bag comprising a multi-layer film for vacuum packaging according to claim 13.
